(19) United States
(12) Patent Application Publication
(10) Pub. No.: US 2016/0061422 A1
(43) Pub. Date: Mar. 3, 2016

(54) Installation Liner for Flexible OLED Panels

(71) Applicant: ABL IP Holding, LLC, Conyers, GA (US)

(72) Inventors: Michael Evenson, Rushford, MN (US); Min-Hao Michael Lu, Castro Valley, CA (US)

(21) Appl. No.: 14/843,767

(22) Filed: Sep. 2, 2015

Related U.S. Application Data
(60) Provisional application No. 62/044,795, filed on Sep. 2, 2014.

(51) Int. Cl. F21V 19/00; H01L 51/56; H01L 51/52

(52) U.S. Cl. CPC F21V 19/002; H01L 51/5237; H01L 51/56; F21Y 2105/008

(57) ABSTRACT

A thin, relatively stiff installation liner is pre-bent in a desired curved plane matching the curved plane of the luminaire support structure of a luminaire on which an OLED panel is to be installed. The liner gives the panel mechanical support and fixes the panel in a desired curvature to allow the panel and liner to be easily assembled in luminaire products.

### CROSS-REFERENCE TO RELATED APPLICATIONS

This application claims the benefit of U.S. Provisional Patent Application No. 62/044,795 filed Sep. 2, 2015.

### BACKGROUND

The present invention generally relates to luminaires having OLED light sources and more particularly relates to the installation of flexible OLED light sources in luminaires requiring that the OLEDs lie in a curved plane.

The challenge of assembling a luminaire with flexible OLED panels that must lie in a curved plane is the difficulty in positioning the OLED in the luminaire's curved support structure for the OLED panels. First, there is the risk of the damage. Current commercially available OLED panels use a thin glass substrate which, while bendable, remains fragile and breakable when being handled and particularly when being bent. Second, there is the difficulty in handling the OLED panel itself as it is being bent. A flexible OLED panel tends to bounce back into its original flat position when it is bent. Maintaining a bend as the panel is manipulated into place on the luminaire support structure can be a challenge to the assembler who must not only properly position the panel but secure it in place.

The present invention facilitates the building of OLED luminaires that use flexible OLED panels that must be bent in a curved plane in order to be installed. The invention makes it easier for the assembler to handle the flexible OLED panel during the installation process and reduces the risk that the panel will be damaged.

### SUMMARY OF INVENTION

The present invention is directed to a thin, relatively stiff installation liner that is pre-bent in a desired curved plane matching the curved plane of the luminaire support structure of a luminaire on which an OLED panel is to be installed. The liner gives the panel mechanical support and fixes the panel in a desired curvature to allow the panel and liner to be easily assembled in luminaire products. The present invention is also directed to a method of installing an OLED panel in curved plane in a luminaire using such an installation liner.

The installation liner has a thin, substantially rigid body that extends in a curved plane and that has opposite sides, one of which is a convex side and the other of which is a concave side. The substantially rigid body further has opposite end edges defining the length of the liner body. The length of the liner body can be comparable to the length of the OLED panel to be installed on a luminaire body using the liner, and the overall footprint of the liner body will preferably substantially match the footprint of the OLED panel. An edge capture structure can be provided on at least one of the end edges of the liner body, and will be associated with one of the opposite curved sides of the liner body.

The OLED panel can be manually bent over the curved side of the liner body with which the edge capture structure is associated with the liner body providing mechanical support for the OLED panel along the curved plane of the liner. One of the edges of the OLED panel defining the length of the OLED panel can be manually engaged in the liner body's edge capture structure to maintain the OLED panel in the curved plane of the liner body as the OLED panel and liner are installed on a luminaire body.

In one aspect of the invention, an edge capture structure is provided on only one edge of the liner body, and in another aspect of the invention, an edge capture structure is provided on opposite end edges of the liner body.

In a further aspect of the invention, the low profile edge capture structure is situated to capture the edge or edges of the OLED panel so that the panel can be bent over the convex side of the liner body. And in still another aspect of the invention, the low profile edge capture structure is situated to capture the edge or edges of the OLED panel so that the panel can be bent over the concave side of the liner body.

### BRIEF DESCRIPTION OF THE DRAWINGS

FIG. 1 is a top front perspective view of an OLED luminaire having a curved body for supporting the OLED panels and showing a curved OLED panel on the front of the luminaire body.

FIG. 2 is a top rear perspective view thereof showing a curved OLED panel on the rear of the luminaire body opposite the front OLED panel.

FIG. 3 is an enlarged partial cross-sectional view of the luminaire illustrated in FIGS. 1 and 2, showing the OLED panels seen in FIGS. 1 and 2 mounted on opposite sides of the curved body of the luminaire and further showing curved OLED liners in accordance with the invention used to facilitate installation of the OLED panels.

FIG. 4 is a top perspective view of one embodiment of an installation liner in accordance with the invention.

FIG. 5 is a top plan view thereof.

FIG. 6 is a side elevational view thereof.

FIG. 6A is an enlarged fragmentary view thereof taken along lines 6A-6A in FIG. 6 showing in greater detail the configuration of the edge capture structure at the ends of the liner.

FIG. 7 is a top perspective view of another embodiment of an installation liner in accordance with the invention.

FIG. 8 is a side elevational view thereof.

FIG. 8A is an enlarged fragmentary view thereof taken along lines 8A-8A in FIG. 8 showing in greater detail the configuration of the capture elements at the ends of the liner.

FIG. 9 is a side perspective view of the liner shown in FIGS. 4-6A with a flexible OLED bent over and captured by the installation liner shown in FIGS. 4-6A.

FIG. 10 is a bottom plan view of the liner and captured OLED positioned in a curved frame structure of a luminaire.

### DESCRIPTION OF ILLUSTRATED EMBODIMENTS

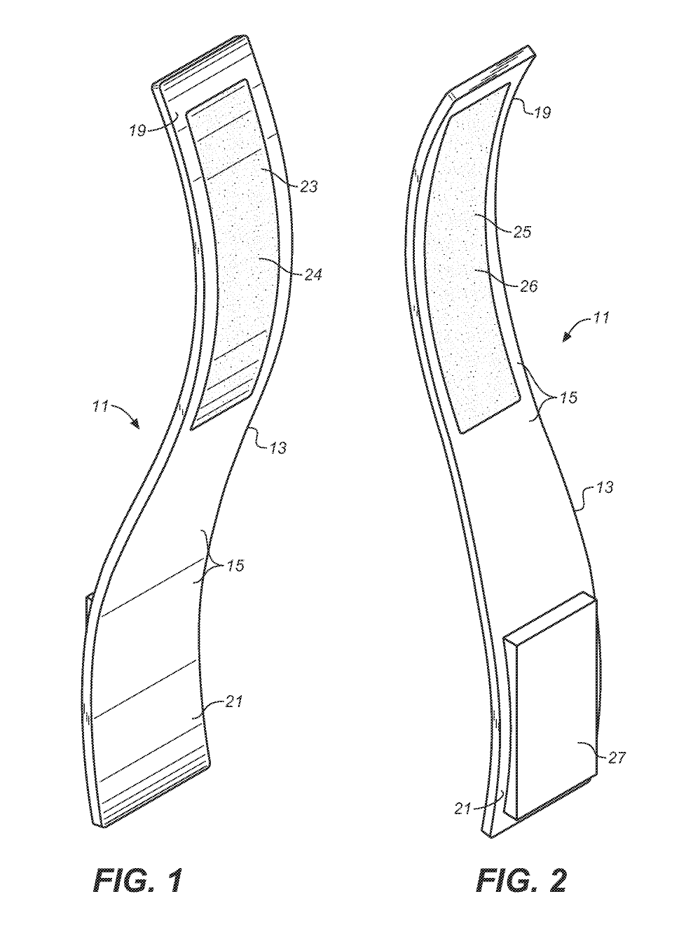

Referring now to the drawings, FIGS. 1-2 show a wall mounted OLED luminaire of the type in which the installation has particular application. The luminaire, denoted by the numeral 11, is seen to have a relatively thin curved body 13 having a front side 15, a back side 17, a top end 19, and a bottom end 21. Two thin OLED panels 23, 25 are provided at the top end of the curved body, one on the front side 15 and one on the back side 17, and a mounting block 27 is provided on the back side of the curved body at the bottom end of the body for mounting the luminaire to a wall or other vertical surface.

Each of the OLED panels 15, 17 is seen as lying in a curved plane conforming to the curvature of the luminaire body, and each panel has a curved light emitting surface 24, 26 that faces away from the body. The light emitting surface of the OLED panel on the front side of the luminaire body produces ambient lighting within the space, while the light emitting surface of the OLED panel on the back side of the luminaire body emits light that washes the wall or other vertical surface to which the luminaire is mounted. The challenge in assembling the parts of an OLED luminaire having curved planes such as illustrated in FIGS. 1-2 is to bend and install the OLED panels on the body of the luminaire and to do so without breaking or damaging the fragile OLED panels.

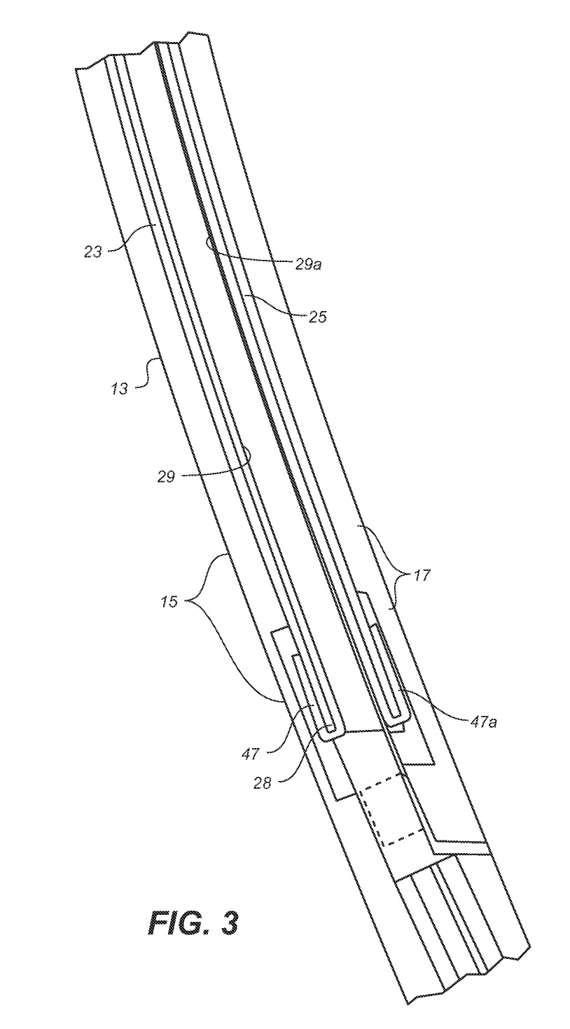

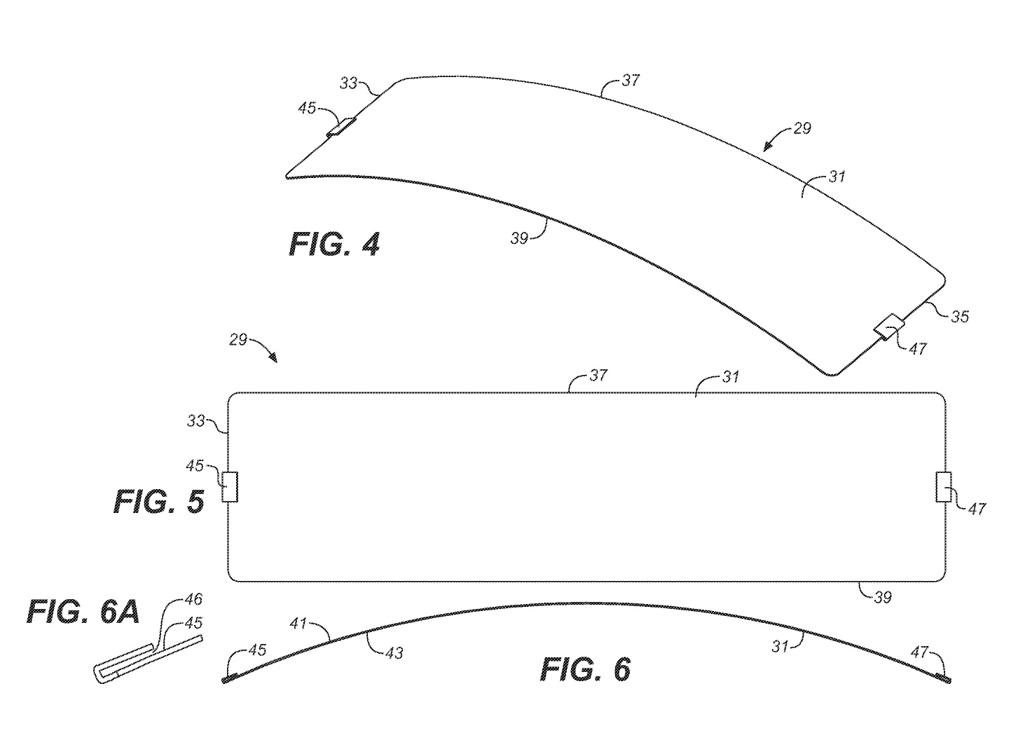

FIG. 3 is an enlarged fragmentary sectional view of the top of the luminaire shown in FIGS. 1 and 2. FIG. 3 shows the two OLED panels 23, 25 installed in the thin body 13 of the luminaire, and further shows each of the OLED panels backed by an installation liner 29 such as illustrated in FIGS. 4-6A. The installation liner makes it easier for the assembler to handle the flexible OLED panel during the installation process and reduces the risk that the panel will be damaged or destroyed during the installation process.

Referring to FIGS. 4-6A, installation liner 29 is seen to have a thin, substantially rigid body 31 that extends in a curved plane and that has opposite sides, one of which is a convex side 41 and the other of which is a concave side 43. The substantially rigid body further has opposite end edges 33, 35 defining the length of the liner, and lengthwise side edges 37, 39 defining the width of the liner. The length of the liner can be comparable to the length of the OLED panel to be installed on a luminaire body using the liner, and will preferably have a length that is slightly shorter than the length of the OLED panel. Most preferably, the footprint of the curved body as defined by the body's length and width will substantially match the footprint of the OLED panel, after the OLED panel is bent on the liner as hereinafter described.

Low profile edge capture structures are provided on the length defining opposite end edges 33, 35 of the liner body for catching and holding the OLED panel when or as the panel in bent on the liner. In FIGS. 4-6A, it is seen that the edge capture structures are in the form of bent over tabs 45, 47, which are centered on the end edges 33, 35 of the liner body, and which are associated with convex side 41 of the liner body; that is, the tabs are bent over in the direction of the convex side to create a retention channel 46 on the convex side of the liner body. Thus, the installation liner illustrated in these figures would be used to bend an OLED panel over the liner's convex side. Such a liner is used to hold the panel 23 of the luminaire shown in FIGS. 1-3. For bending and holding an OLED panel in a concave plane, such as OLED panel 25 shown in FIGS. 1-3, the tabs 45, 47 would be bent back in the other direction towards the concave surface, such as shown in FIG. 3 with respect to liner 29a and tab 47a.

While the relatively bent over short tabs are provided on the installation liner illustrated in FIGS. 4-6A, it is contemplated that the capture structures at the end edges of liner body 31 could be provided in other forms, such as a series of tabs or an elongated channel extending substantially the width of the liner body. However, the illustrated short tabs have the advantage that they minimize contact with the edges of the OLED panel and allow ample room for accommodating the electrical lead wires for the OLED panel.

As mentioned, the liner body is preferably a relatively thin body. Suitably the body can be a stamped and bent sheet aluminum part having a suitable thickness of about 0.015 inches (0.381 mm). Flexible OLED panels that can suitably be used with the installation liner include LG Chem F6BA30, F6BA35 and F6BA40 OLED panels, which have a thickness of 0.42 mm.

To use the installation liner 29 illustrated in FIGS. 4-6A, a comparably sized OLED panel, such as OLED panel 23 shown in FIGS. 1-3, is first placed against the convex side 41 of the liner body with its light emitting surface facing away from this convex surface. The OLED panel can then be manually bent over the convex side of the liner body with a slight over-bend so that the end edges (such as the edge 28 shown in FIG. 3) of the OLED panel can be perched in front of the retention channels formed by the liner body's bent over end tabs 45, 47. During this bending process, the convex side of the liner body will provide a curved mechanical support for the OLED panel and prevent any creasing of the panel. Once the panel is in place, the over-bend can be released to allow the ends of the OLED panel to slide into the retention channels formed by the liner body end tabs. The curved liner will maintain the OLED panel in a curvature that matches the curved plane of the liner's substantially rigid body as the OLED panel and liner are installed on a luminaire body.

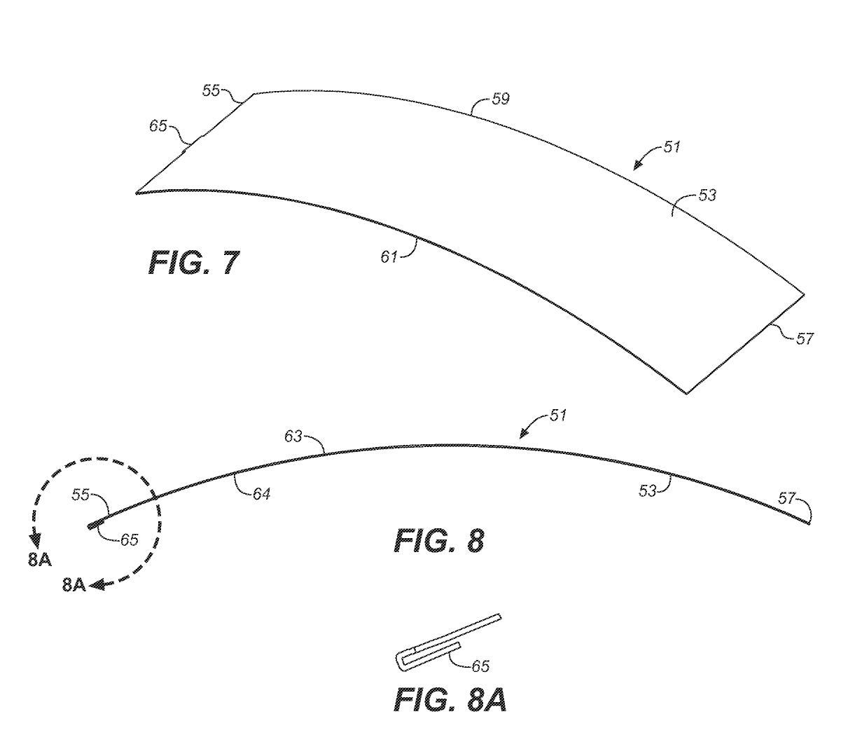

The installation liner just described can be referred to as a double ended liner in that the liner body has a capture structure at each end of the liner. FIGS. 7-8A illustrate an alternative embodiment of the installation liner, which is a single ended liner. In this embodiment the, liner body 53 similarly extends in a curved plane and has a convex side 63, a convex side 64, opposite end edges 55, 57 defining the length of the liner, and lengthwise side edges 59, 61 defining the width of the liner. In this embodiment the length of the liner does not have to be as closely matched to the length of the OLED but is preferably about the same length. Again, the footprint of the curved body as defined by the body's length and width will most preferably substantially match the footprint of the OLED panel, after the OLED panel is bent on the liner.

On this single ended liner there is only one OLED edge capture structure, namely, bent tab 65 centered on the liner body's end edge 55. The opposite end edge of the body has no capture structure. With this embodiment, the OLED panel need not be over-bent in order to engage the capture structure. One end of the OLED panel can be inserted into the single capture structure and then bent over the curved surface of the liner. The free end of the panel can be held down by hand as the panel and liner are installed on the body of the luminaire, whereupon the liner-panel unit can be fastened in place by a suitable cover, bracket or frame.

It is also seen the installation liner illustrated in FIG. 7-8A differ from the previously described embodiment, in that, the single catch member is associated with the concave instead of the convex side of liner body 53. That is, the bent tab 65 is bent over in the direction of the concave side of the liner body to form a retention channel on that side of the body. Thus, in this embodiment an OLED panel would be placed on the concave side of the liner to provide a concave outwardly facing light emitting surface, as is the case with OLED 25 shown in FIGS. 1-3.

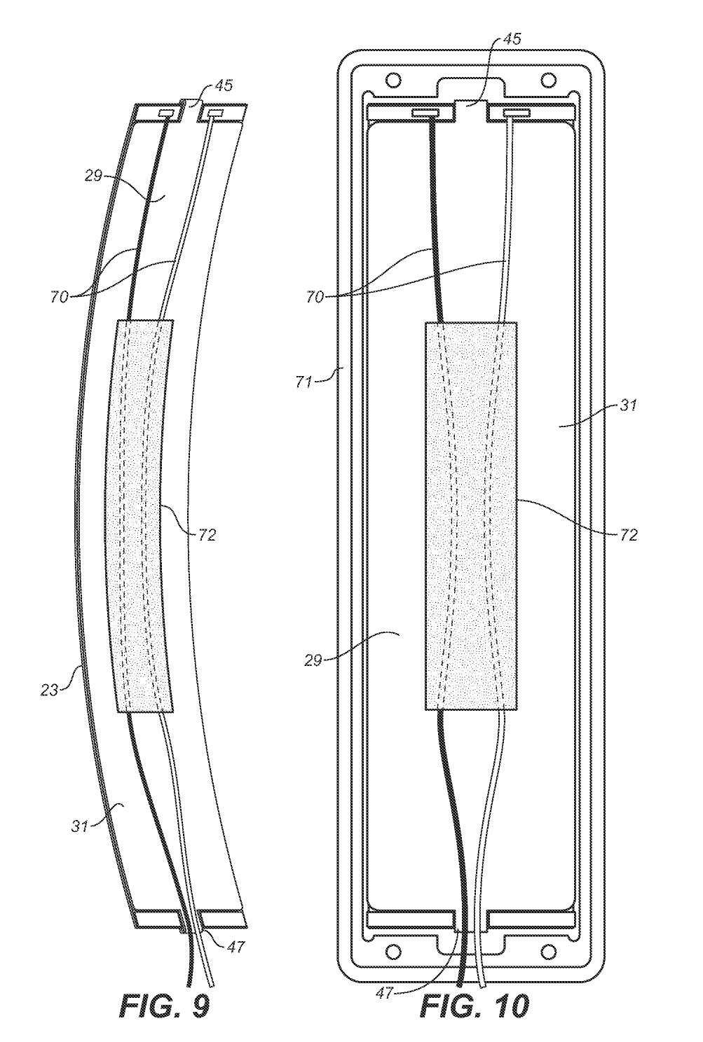

FIGS. 9 and 10 show a flexible OLED panel, such as OLED panel 23, shown in FIGS. 1-3, captured and held in a curved plane by an installation liner, such as installation liner 29 shown in FIGS. 4-6A. These figures also show how the lead wires 70 of the OLED panel can be accommodated behind the liner body. It is seen that there is space next to bent over tabs 45, 47 to accommodate the wires, that the wrap around the length defining opposite edges 33, 35 of the liner body next to the tabs. To improve wire management, a strip of adhesive material, such as a strip of Kapton tape 72, can suitably be used to hold the wires against the back of the liner body 31.

FIG. 10 additionally shows how the combination of the OLED panel and installation liner shown in FIG. 9 can be fitted into a thin profile structural frame element 71 of a thin profile luminaire such as shown in FIGS. 1-3. Within the curved plane, the OLED-liner combination has a very low profile with the largest thickness being created by the bent over low profile catch tabs 45, 47. The radius of curvature of the installation liner will be dictated by the product with which it is used, in this case the radius of curvature of frame 71. To avoid shape bends, the radius of curvature will usually be relatively large. For example, in the illustrated embodiments the radius of curvature is about nine inches.

While different embodiments of the present invention have been described in considerable detail in the foregoing specification, it is not intended that the invention be limited to such detail, except as necessitated by the following claims.

We claim:

1. An installation liner for installing a flexible OLED panel on a luminaire body in a curved plane, wherein said OLED panel includes opposite edges defining the length of the panel, said installation liner comprising:
a thin, substantially rigid body extending in a curved plane and having opposite sides, one of said opposite sides being a convex side and the other of said opposite sides being a concave side, said substantially rigid body further having opposite end edges defining the length of the liner, wherein the length of the liner is comparable to the length of the OLED panel to be installed on a luminaire body using the liner, and
an edge capture structure on at least one of the length defining opposite end edges of said substantially rigid body and associated with one of the opposite sides of said body, wherein at least one of the edges of the OLED panel defining the length of the OLED panel can be manually engaged in said edge capture structure, such that the OLED panel can be manually bent over the side of the rigid body with which the edge capture structure is associated, and such that engagement of the at least one edge of the OLED panel in the edge capture structure permits the OLED panel to be maintained in a curvature substantially matching the curved plane of said rigid body, and such that the curved OLED panel and the liner can be readily installed on a luminaire body in a curved plane.

2. The installation liner of claim 1 wherein said substantially rigid body has a footprint and said footprint substantially matches the footprint of the OLED panel to be installed on a luminaire body using the liner.

3. The installation liner of claim 1 wherein an edge capture structure is provided on both of the length defining end edges of said substantially rigid body.

4. The installation liner of claim 1 wherein an edge capture structure is provided on only one of the length defining end edges of said substantially rigid body.

5. The installation liner of claim 1 wherein said at least one edge capture structure is bent over tab on one of the length defining end edges of said substantially rigid body, said bent over tab forming a retention channel at the at least one end edge of the substantially rigid body adapted for capturing the edge of an OLED panel engaged therein.

6. The installation liner of claim 1 wherein said at least one edge capture structure is associated with the convex side of said substantially rigid body, wherein an OLED panel engaged in said edge capture structure can be manually bent over the convex side of the rigid body.

7. The installation liner of claim 1 wherein said at least one edge capture structure is associated with the concave side of said substantially rigid body, wherein an OLED panel engaged in said edge capture structure can be manually bent over the concave side of the rigid body.

8. An installation liner for installing a flexible OLED panel on a luminaire body in a curved plane, wherein said OLED panel includes opposite edges defining the length of the panel, said installation liner comprising:
a thin, substantially rigid body extending in a curved plane and having opposite sides, one of said opposite sides being a convex side and the other of said opposite sides being a concave side, said substantially rigid body further having a footprint defined in part by opposite end edges which define the length of the liner, wherein the footprint of the liner body substantially matches the footprint of the OLED panel to be installed on a luminaire body using the liner, and
at least one bent over tab on at least one of the length defining opposite end edges of said substantially rigid body and associated with one of the opposite sides of said body, said bent over tab forming a retention channel at the at least one end edge of the substantially rigid body adapted for capturing the edge of an OLED panel engaged therein, wherein at least one of the edges of the OLED panel defining the length of the OLED panel can be manually engaged in said retention channel, such that the OLED panel can be manually bent over the side of the rigid body with which said bent over tab is associated, and such that engagement of the at least one edge of the OLED panel in the bent over tab permits the OLED panel to be maintained in a curvature substantially matching the curved plane of said rigid body, and such that the curved OLED panel and the liner can be readily installed on a luminaire body in a curved plane.

9. The installation liner of claim 8 wherein said at least one bent over tab is associated with the convex side of said substantially rigid body, wherein an OLED panel engaged in the retention channel formed by said bent over tab can be manually bent over the convex side of the rigid body.

10. The installation liner of claim 8 wherein said at least bent over tab is associated with the concave side of said substantially rigid body, wherein an OLED panel engaged in the retention channel formed by said bent over tab can be manually bent over the concave side of the rigid body.

11. A method of installing a flexible OLED panel in a convex plane in the body of a luminaire body wherein the OLED panel has a light emitting surface, comprising:
providing an installation liner having a thin, substantially rigid body extending in a curved plane and having opposite curved sides, one of said curved sides being a convex side and the other of said curved sides being a concave side, said installation liner being chosen in accordance with the OLED curvature configuration requirement and of the luminaire,
placing the flexible OLED panel against one of the curved sides of the installation liner body with the light emitting surface of the OLED panel facing away from the liner body, the side of the liner body being chosen depending on the OLED curvature configuration requirement of the luminaire,
bending the OLED panel over the chosen curved side of the installation liner body, and
with the OLED panel bent over the installation liner body, installing the OLED panel and installation liner in the luminaire.

12. The method of claim 11 wherein an edge capture structure is provided on at least one end edge of the body of the installation liner and is associated with the chosen curved side of liner body over which the OLED panel is to be bent, and wherein, prior to bending the OLED panel over the chosen curved side of the installation liner body, an edge of the OLED panel is engaged in the edge capture structure of the liner body.

13. The method of claim 11 wherein an edge capture structure is provided on opposite end edges of the substantially rigid body of the installation liner and are associated with the chosen curved side of liner body over which the OLED panel is to be bent, and wherein opposite edges of the OLED panel are engaged in the edge capture structures of the liner body prior to installing the OLED panel and installation liner in the luminaire.

14. The method of claim 11 wherein, in connection with installing the OLED panel and installation liner in the luminaire, the OLED panel and installation liner are fitted into a thin profile structural frame element having a curved profile substantially matching the curvature of the body of the installation liner, and wherein said structural frame element comprises a structure element of a thin profile luminaire.
